(19) United States
(12) Patent Application Publication
(10) Pub. No.: US 2025/0309126 A1
(43) Pub. Date: Oct. 2, 2025

(54) High Bandwidth Memory Buffer Bridge Die in Routing Substrate

(71) Applicant: Apple Inc., Cupertino, CA (US)

(72) Inventor: Jun Zhai, Cupertino, CA (US)

(21) Appl. No.: 19/063,131

(22) Filed: Feb. 25, 2025

Related U.S. Application Data
(60) Provisional application No. 63/571,805, filed on Mar. 29, 2024.

(51) Int. Cl. H01L 23/538; H01L 23/00; H01L 25/18; H10B 80/00; H10D 80/30

(52) U.S. Cl. CPC H01L 23/5385; H01L 23/5386; H01L 25/18; H10B 80/00; H10D 80/30; H01L 24/16; H01L 2224/16145; H01L 2224/16227; H01L 2924/1432; H01L 2924/1436

(57) ABSTRACT

Memory systems and methods of assembly are described in which a memory system includes a routing substrate, a processor on a first side of the routing substrate, a memory die stack on the first side of the routing substrate, and a buffer bridge die embedded in the routing substrate and electrically connecting the memory die stack with the processor.

### RELATED APPLICATIONS

This application claims the benefit of priority of U.S. Provisional Application No. 63/571,805, filed Mar. 29, 2024, which is herein incorporated by reference.

### BACKGROUND

### Field

Embodiments described herein relate to memory systems, and more particularly to high bandwidth memory systems.

### Background Information

Memory storage is an integral part of electronic devices such as personal computers, servers, gaming consoles, and mobile devices. Memory storage can be a particularly important component in high performance computing (HPC) and highly niche workloads such as artificial intelligence, analytics, edge computing, etc. that require high bandwidths and high speed data access. While double data rate (DDR) memory solutions are able to meet most practical needs, the more recent introduction of high bandwidth memory (HBM) provides a memory platform that can achieve higher bandwidth while using less power and a substantially smaller form factor than DDR. This is achieved by vertical stacking of multiple dynamic random access memory (DRAM) dies and onto a logic die that commonly includes buffer circuitry and test logic, and is also commonly referred to as a buffer die. HBM has a wider memory bus than DDR with a larger number of channels driven at lower data rates, which can translate to lower energy consumption compared to DDR. HBM also comes at a significant cost compared to DDR due to inclusion of an interposer used to accommodate the larger number of channels and fine wiring density.

### SUMMARY

Memory systems, and in particular HBM systems, and methods of assembly are described in which a memory system includes a routing substrate, a processor on a first side of the routing substrate, a memory die stack (e.g., DRAM die stack) on the first side of the routing substrate, and a first buffer bridge die embedded in the routing substrate and electrically connecting the memory die stack with the processor. The first buffer bridge die may include circuitry common for HBM including serialization/deserialization (SerDes) circuitry, buffering circuitry, error correction circuitry, and test circuitry. The memory die stack can include any suitable number of memory dies such as 8 or 12, depending upon the memory system generation. In accordance with embodiment the memory die stack does not include a logic die, and instead this circuitry is offloaded to the first buffer bridge die. The memory system configurations in accordance with embodiments can also expand the types of routing substrates available, which do not necessarily require a silicon base substrate. The routing substrate may nevertheless be mounted onto a system substrate similar to traditional HBM configurations.

The memory die stacks in accordance can also be arranged in rows and columns adjacent to an edge of the processor. In an embodiment the memory die stack is one of a first plurality of memory die stacks in a first column. Each memory die stack of the first plurality of memory die stacks may be connected to the processor with a corresponding buffer bridge die. In an alternative configuration, each memory die stack of the plurality of memory die stacks can be connected to the processor with the first buffer bridge die. In an embodiment a second plurality of memory die stacks can be arranged in a second column adjacent to the first column. In such a configuration, a second buffer bridge die can also be embedded in the routing substrate, and electrically connected to a second memory die stack of the second plurality of memory die stacks.

Bridge routing chiplets may additionally be embedded into the routing substrate in order to connect various buffer bridge dies. In an embodiment, a bridge routing chiplet connects channel routing from the second buffer bridge die to the first buffer bridge die. Furthermore, the bridge routing chiplet can be completely passive, with no active devices, or alternatively can be an active die in which case it may include repeaters and/or redrivers/retimers. Such repeaters and/or redrivers/retimers can alternatively be added to a bridge routing chiplet closer to the processor. In accordance with embodiments, both the first and second buffer bridge dies can include circuitry such as serialization/deserialization (SerDes) circuitry, buffering circuitry, error correction circuitry, and test circuitry. In an embodiment the first buffer bridge die includes repeaters and/or redrivers/retimers coupled with the channel routing from the second buffer bridge die.

### BRIEF DESCRIPTION OF THE DRAWINGS

FIG. 1 is a schematic cross-sectional side view illustration of a conventional HBM system.

FIG. 2A is a schematic cross-sectional side view illustration of a memory system including embedded buffer bridge dies in accordance with an embodiment.

FIG. 2B is a schematic bottom-top view illustration of a memory system including embedded buffer bridge dies in accordance with an embodiment.

FIGS. 2C-2D are schematic bottom-top view illustrations of a memory system with different sizes of embedded buffer bridge dies and bridge routing chiplet in accordance with an embodiment.

FIGS. 3A-3E are schematic cross-sectional side view illustrations for a sequence of forming a memory system with a routing substrate-first approach in accordance with embodiments.

FIGS. 4A-4D are schematic cross-sectional side view illustrations for a sequence of forming a memory system with a routing substrate-last approach in accordance with embodiments.

FIG. 5 is a schematic cross-sectional side view illustration of a heterogenous memory system including embedded buffer bridge dies in accordance with an embodiment.

FIG. 6 is a schematic cross-sectional side view illustration of a heterogenous memory system including embedded buffer bridge dies in accordance with an embodiment.

FIG. 7 is a schematic cross-sectional side view illustration of a memory system including an embedded buffer bridge die in accordance with an embodiment.

### DETAILED DESCRIPTION

Embodiments describe memory systems, such as HBM systems, and methods of fabrication including a memory die stack, a processor, a routing substrate, and a buffer bridge die embedded in the routing substrate. Specifically, the processor can include a central processing unit (CPU), graphics processing unit (GPU), artificial intelligence (AI) accelerator, neural network processor, system on chip (SoC), or other unit that processes data. The routing substrate can be formed of a variety of materials, such as a redistribution layer (RDL), silicon interposer, glass interposer, printed circuit board, etc. Memory die stacks in accordance with embodiments may be strictly limited to memory dies, without a lower logic (buffer) die. Specifically, the memory die stack may be a DRAM die stack for HBM. The number of memory dies may be 8, 12, etc. depending upon the generation of the memory system. The buffer bridge die in accordance with embodiments can include circuitry for traditional HBM, including serialization/deserialization (SerDes), buffering, error correction, and test. Additionally, the buffer bridge die can include channel routing for die-to-die connection between the memory die stack and the processor. In some embodiments, the buffer bridge die can include repeaters and/or redrivers/retimers for longer channel reach.

In one aspect, the embodiments decouple the buffer/logic die of vendor HBM and embed the circuitry for buffering, serializing/deserializing, error correction etc. into a routing substrate (e.g., RDL, interposer). This can allow for longer channels, additional rows of memory die stacks, more control over the memory management and making heterogenous memory solutions (e.g., HBM and DDR). The buffer bridge dies can be passive or active, and may include repeater/retimer circuitry to enable longer routes from the processor to memory. Inclusion of the channel routing into the buffer bridge dies can additionally leverage fine processing conditions and capabilities associated with active silicon fabs used for fabrication of the buffer bridge dies.

In another aspect, embodiments can reduce total cost of the memory system by reducing active silicon area. For example, one or more buffer bridge dies can replace the silicon interposer found in traditional HBM systems, significantly reducing the amount of active silicon required. Furthermore, the one or more buffer bridge dies can be fragmented into passive or active bridge routing chiplet(s) for signal relay, which can provide the fine wiring required at lower cost by either eliminating active silicon altogether or using a less expensive processing node for specific circuitry. The buffer bridge dies in accordance with embodiments can additionally be custom designed to minimize energy and maximize the data rate, bandwidth and channel length. The cost of active silicon can be attributed to both the time and expense related to fabrication of active devices in the silicon, as well as time and cost of fabricating build-up routing structures, which commonly include low dielectric constant materials deposited using time consuming vapor deposition techniques. Routing for passive bridge routing chiplets and/or routing substrate can be achieved outside of the active silicon fab, saving processing time and cost.

Where multiple buffer bridge dies are integrated into the memory system the multiple buffer bridge dies may be identical in shape and circuitry, or may have different shape and/or circuitry. Core circuitry such as buffering, serializing/deserializing, error correction may be similar in different groups of buffer bridge dies. Certain circuitry may optional be present in one buffer bridge die and shared by multiple buffer bridge dies. One group of buffer bridge dies may have additional circuitry, such as repeaters and/or redrivers/retimers for longer channel reach, not found in another group of buffer bridge dies in the same memory system.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

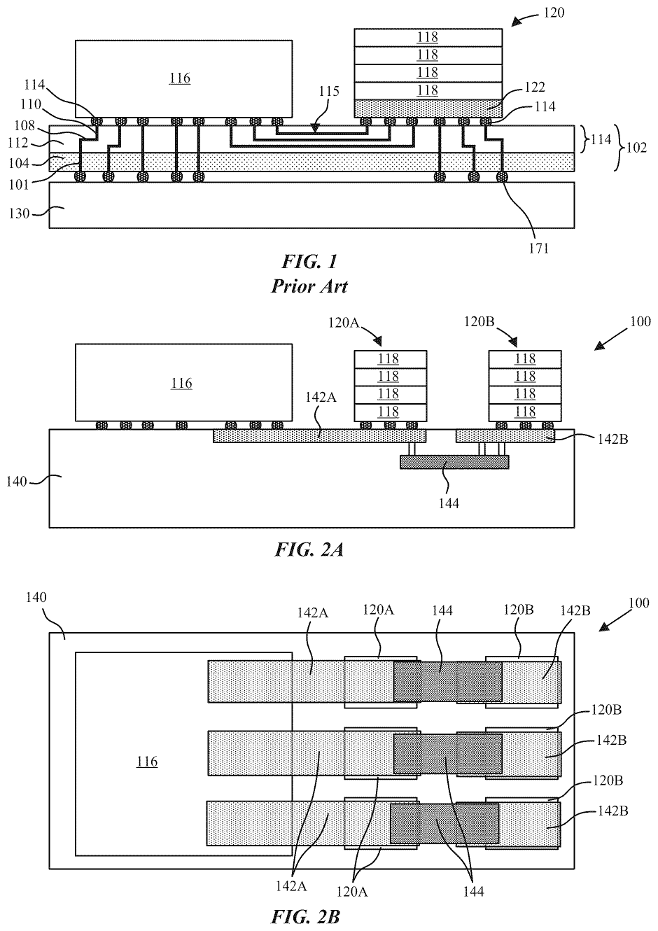

Referring now to FIG. 1 a cross-sectional side view illustration is provided of a conventional HBM system. As shown, this may include a silicon interposer 102 including a base silicon substrate 104 and routing layer 106 over the base silicon substrate. The routing layer may include a plurality of metal redistribution lines 108, vias 110 and dielectric layers 112. The various routing layers and vias may additionally form die-to-die routing 115 between a memory die stack 120 and processor 116 which can both be flip chip mounted onto a same side of the silicon interposer 102 with solder bumps 114 (e.g., micro bumps). The memory die stack 120 may include a plurality of memory dies 118, such a DRAM dies, and a buffer die 122.

The silicon interposer 102 may additionally include through vias 101, such as through silicon vias (TSVs), for back side connection with a system substrate 130, such as a printed circuit board (PCB). For example, connection may be with a plurality of solder bumps 171, pins, etc. The system substrate can be a package substrate or substrate for larger module including additional components mounted thereon. As shown, electrical routing within the silicon interposer 102 can provide direct connection between the system substrate 130 and the processor 116 and/or memory die stack 120 (e.g., HBM), as well as the die-to-die routing 115 corresponding to the channels.

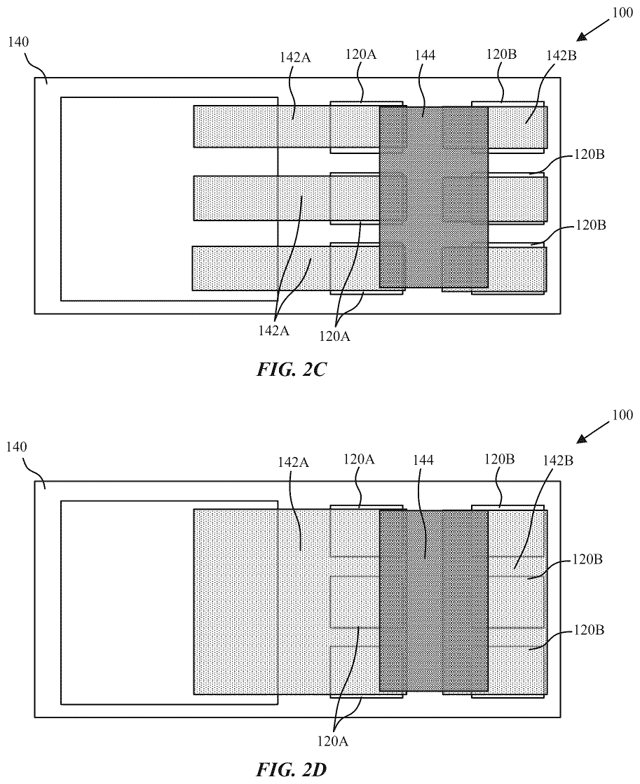

Referring now to FIGS. 2A-2B, FIG. 2A is a schematic cross-sectional side view illustration of an HBM system including embedded buffer bridge dies in accordance with an embodiment; FIG. 2B is a schematic bottom-top view illustration of an HBM system including embedded buffer bridge dies in accordance with an embodiment. As shown, the memory system 100 can include a routing substrate 140 including one or more embedded buffer bridge dies 142A, 142B, which are embedded in the routing substrate 140. Where a plurality of embedded buffer bridge dies 142A, 142B exist they may be electrically connected with the bridge routing chiplet 144, also embedded within the routing substrate 140. As shown the memory die stacks 120A, 120B include a plurality of memory dies 118 (e.g., DRAM), and do not include a stacked buffer die. As such, the memory die stacks 120A, 120B only include memory dies 118. The memory die stacks 120A, 120B can be electrically connected with the processor 116 through one or more embedded buffer bridge dies 142A, 142B and bridge routing chiplet(s) 144.

The embedded buffer bridge dies 142A, 142B in accordance with embodiments can include the traditional buffer die circuitry for serialization/deserialization (SerDes), buffering, error correction, and test. Additionally, the buffer bridge dies can include channel routing for die-to-die connection between the memory die stack and the processor. In some embodiments, the buffer bridge die can include repeaters and/or redrivers/retimers for longer channel reach.

Offloading the buffer circuitry from the memory die stacks and into the routing substrate 140 can additionally reduce channel length, and facilitate custom circuitry design that is separate from the memory die stacks, potentially creating additional efficiencies when interfacing with the processor 116. The channel length reduction and inclusion of repeaters and/or redrivers/retimers can facilitate longer channel length and the inclusion of multiple columns (A, B) of memory die stacks 120A, 120B, further increasing potential bandwidth of the memory system 100.

Referring specifically to FIG. 2B, a two columns (A, B) of memory die stacks 120A, 120B are illustrated, with each column including a plurality of rows of memory die stacks for a total of six illustrated memory die stacks. While two columns are illustrated it is to be appreciated that embodiments may include a single column of memory die stacks adjacent a processor 116 edge, though embodiment may also facilitate the expansion of memory columns. As shown, even where a single column of memory die stacks 120A is arranged adjacent to a processor 116, a plurality of rows of embedded buffer bridge dies 142A can electrically connect a plurality of memory die stacks 120A with the processor 116. Thus, not only can a significant silicon cost reduction be achieved by removing the traditional silicon interposer 102, silicon area savings can be achieved in both row-wise and column-wise fragmentation of the embedded buffer bridge dies. In other embodiments, a single embedded buffer bridge die 142A can connect a plurality of embedded buffer bridge dies 142A in a same column to the processor 116.

Still referring to FIGS. 2A-2B the bridge routing chiplet(s) 144 can be purely passive and function primarily for channel routing, or can also be active and include repeaters and/or redrivers/retimers to facilitate longer channel length. It is to be appreciated that passive bridge routing chiplet(s) 144 can reduce cost by not requiring active silicon. It may be more cost effective to include any repeaters and/or redrivers/retimers in the embedded buffer bridge dies where the cost of active silicon is already absorbed.

A variety of configurations are possible for arrangement of the buffer bridge dies and bridge routing chiplets depending upon the memory die stack arrangements, cost and bandwidth requirements. Referring to the embodiment illustrated in FIG. 2C a single bridge routing chiplet 144 can connect a plurality of rows and columns of buffer bridge dies. Such a configuration may be cost friendly, particularly without active silicon in the bridge routing chiplet 144. In the embodiment illustrated in FIG. 2D the buffer bridge dies can span multiple rows of memory die stacks. Similarly, a single buffer bridge routing chiplet 144 can be used to connect the larger buffer bridge dies 142A, 142B.

Where multiple buffer bridge dies are integrated into the memory system the multiple buffer bridge dies may be identical in shape and circuitry, or may have different shape and/or circuitry. Core circuitry such as buffering, serializing/deserializing, error correction may be similar in different groups of buffer bridge dies. Certain circuitry may optionally be present in one buffer bridge die and shared by multiple buffer bridge dies. One group of buffer bridge dies may have additional circuitry, such as repeaters and/or redrivers/retimers for longer channel reach, not found in another group of buffer bridge dies in the same memory system. In an embodiment, the first embedded buffer bridge dies 142A include repeaters and/or redrivers/retimers for channels from the second memory die stacks 120B.

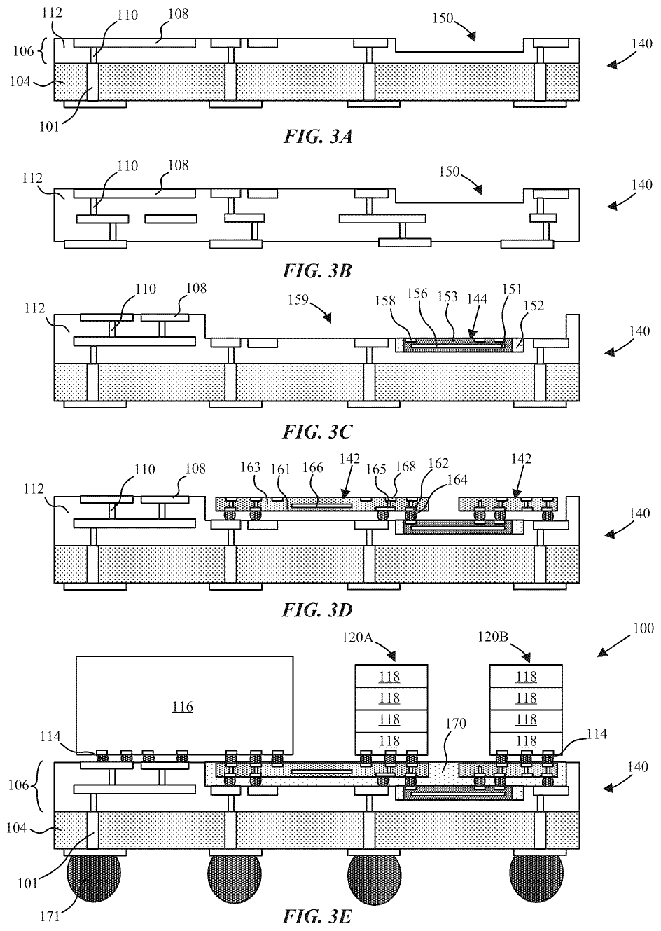

FIGS. 3A-3E are schematic cross-sectional side view illustrations for a sequence of forming a memory system (e.g., HBM system) with a routing substrate-first approach in accordance with embodiments. It is to be appreciated that the processing sequence is significantly simplified, and process variations are contemplated. Referring now to FIG. 3A a partially fabricated routing substrate 140 is shown including a base substrate 104 such as silicon, glass, etc. including a plurality of through vias 101 and a routing layer 106 over the base substrate 104. The routing layer can include a plurality of dielectric layers 112, vias 110 and metal redistribution lines 108. Additionally, a first trench 150 can be formed in the routing layer 106 using a suitable technique.

The base substrate 104 may be integrated in order to provide structural stability to the routing substrate 140, however the base substrate 104 is not required. FIG. 3B illustrates an alternative partially fabricated routing substrate 140 including a plurality of dielectric layers 112, vias 110, metal redistribution lines 108, and first trench 150 similar to that shown in FIG. 3A. The dielectric layers 112, vias 110, and metal redistribution lines 108 of FIGS. 3A-3B can be fabricated using suitable techniques, such as thin film deposition techniques commonly used in forming package redistribution layers (RDLs). For example, the dielectric layers 112 can be formed using liquid solution techniques such as spin coating, slot coating, etc., lamination techniques, or more time consuming techniques such as chemical vapor deposition (CVD) or physical vapor deposition (PVD). Metal vias and redistribution lines can be formed using suitable techniques such as plating, chemical vapor deposition, or lamination. A variety of coarser fabrication techniques may optionally be available for the redistribution lines 108 since the channel wiring represented in the die-to-die wiring in the embedded buffer bridge die(s) and optional bridge routing chiplet(s) 144 can be finer pitch, smaller line widths, and higher density than the surrounding redistribution lines 108.

Referring now to FIGS. 3C-3E, the processing sequence is illustrated continuing with the structure of FIG. 3A, though it is to be appreciated that identical processing sequences can also proceed with the structure of FIG. 3B. In interest of clarity and conciseness, the illustrated processing sequence is shown only with regard to FIG. 3A. As shown in in FIG. 3C, an optional bridge routing chiplet 144 can be placed into the optional first trench 150, which can then be filled with a gap fill material 152, such as epoxy or other material. The bridge routing chiplet 144 may be placed face up with landing pads 158 facing up. The bridge routing chiplet 144 can be formed of a variety of materials. For example, the bridge routing chiplet 144 can include a base substrate 151 (e.g., silicon) and one or more dielectric layers 153 and metal wiring layers 156 and vias (not shown). Together the metal wiring layers 156 and vias can provide die-to-die routing for the plurality of channels. In accordance with embodiments the bridge routing chiplet 144 can be passive, and thus does not include active devices. In other embodiments the bridge routing chiplet 144 can optionally include active devices, such as repeaters and/or redrivers/retimers at a cost.

Following placement of the bridge routing chiplet 144, application of gap fill material 152 and formation of additional layers of the routing substrate 140 one or more second trenches 159 can be formed in the routing substrate 140 exposing the bridge routing chiplet 144, and optionally any redistribution lines 108 (or contact pads connected thereto). One or more buffer bridge dies 142 can then be mounted into the one or more second trenches 159, for example, with flip chip bonding and solder bumps 164 (micro bumps). As shown, the buffer bridge dies 142 can include back side landing pads 162 coupled with the solder bumps 164 a base substrate 161 (e.g., silicon) and one or more dielectric layers 163 and metal wiring layers 166 and vias (not shown). Furthermore, a plurality of through vias 165 (e.g., through silicon vias) can extend through the base substrate 161 for back side connection. Together the metal wiring layers 166 and vias can provide die-to-die routing for the plurality of channels, as well as additional logic routing. In accordance with embodiments the buffer bridge dies 142 can be active dies, with active devices formed in the base substrate 161 in accordance with standard processes. The buffer bridge dies in accordance with embodiments can include circuitry for traditional HBM, including serialization/deserialization (SerDes), buffering, error correction, and test. Additionally, the buffer bridge dies can include channel routing for die-to-die connection between the memory die stack and the processor. In some embodiments, one or more of the buffer bridge dies can include repeaters and/or redrivers/retimers for longer channel reach.

Referring now to FIG. 3E, a gap fill material 170 can be formed around the one or more buffer bridge dies 142 in the one or more second trenches 159 to embed the buffer bridge dies 142 in the routing substrate 140. This may be followed by additional processing and then flip chip attachment of the one or more memory die stacks 120A, 120B and processor 116 onto a same side of the routing substrate 140 for example using solder bumps 114. As shown, the solder bumps can be mounted onto landing pads 168 of the embedded buffer bridge dies 142 and landing pads coupled with the redistribution lines 108 of the routing substrate 140. A plurality of solder bumps 171 can additionally be placed onto landing pads on a back side of the routing substrate 140 opposite the mounted memory die stacks 120A, 120B and processor 116.

In accordance with embodiments electrical routing paths may extend directly from the solder bumps 171 to the processor 116, and also directly to the one or more memory die stacks 120A, 120B. As shown, electrical routing paths may also extend from the solder bumps 171 to the buffer bridge dies 142, and optionally to the bridge routing chiplet 144.

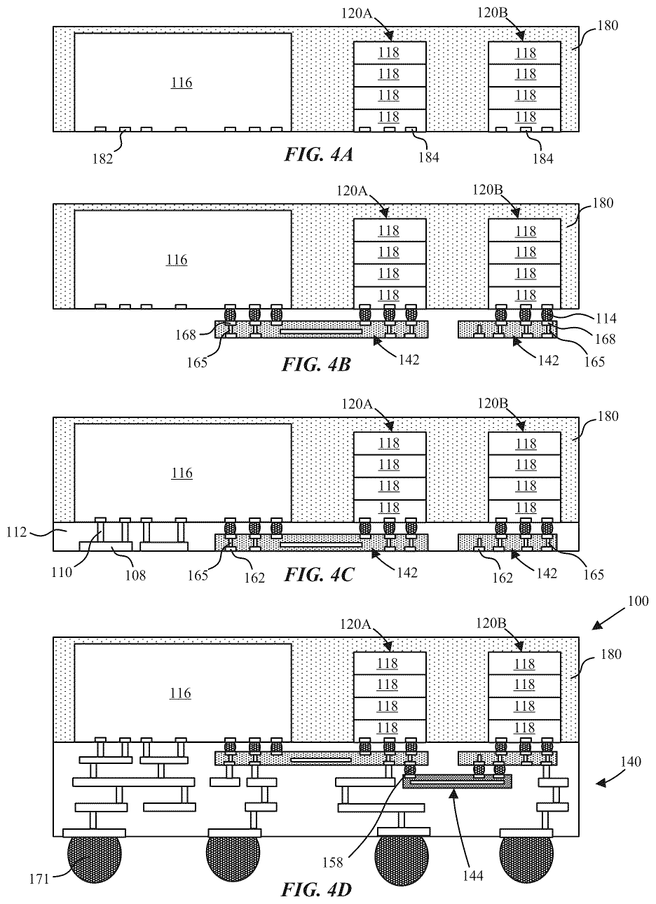

The memory systems 100 in accordance with embodiments can also be fabricated using a routing substrate-last approach. FIGS. 4A-4D are schematic cross-sectional side view illustrations for a sequence of forming a memory system (e.g., HBM system) with a routing substrate-last approach in accordance with embodiments. It is to be appreciated that the processing sequence is significantly simplified, and process variations are contemplated. As shown in FIG. 4A, a reconstituted structure is illustrated in which a processor 116 and one or more memory die stacks 120A, 120B are encapsulated in a molding compound layer 180, with processor 116 landing pads 182 and memory die stack landing pads 184 exposed. One or more buffer bridge dies 142 can then be mounted onto the exposed landing pads with solder bumps 114. As shown in FIG. 4B, a first buffer bridge die 142 is mounted on both landing pads 182 of the processor 116 and landing pads 184 of one or more of the inner-most column memory die stack(s) 120A. A second buffer bridge die 142 is also mounted onto the landing pads 184 of one or more memory die stacks 120B in a second column, and so on for additional column expansion.

The routing substrate dielectric layers 112, vias 110 and redistribution lines 108 can then be partially fabricated, leaving landing pads 162 of the buffer bridge dies 142 exposed as shown in FIG. 4C. This can be followed by mounting of an optional bridge routing chiplet 144 onto the landing pads 184 using solder bumps 164 as shown in FIG. 4D, followed by completion of the routing substrate 140 and placement of solder bumps 171.

While embodiments up to this point have been illustrated with regard to homogenous memory die stacks, multiple columns of memory die stacks, and multiple bridge routing chiplets 144 a variety of alternative configurations are envisioned.

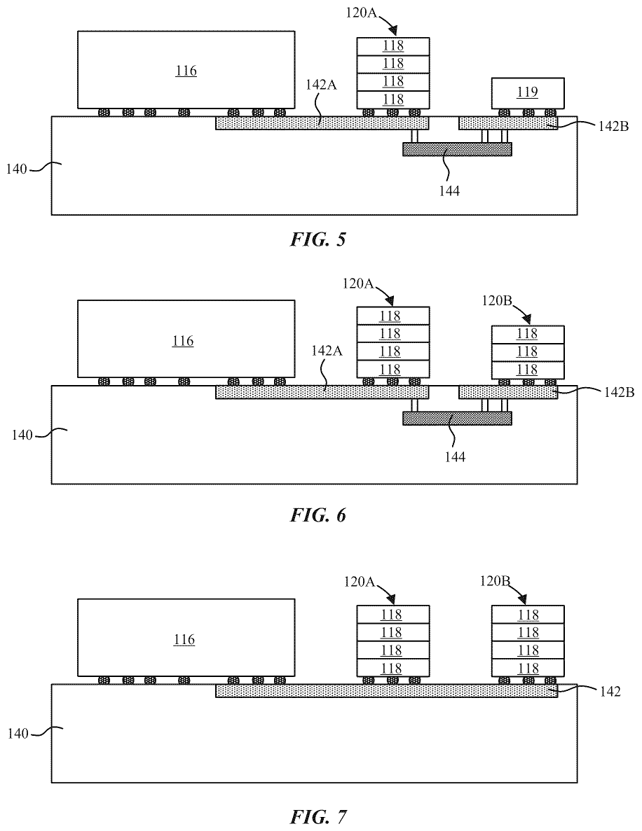

Referring now to FIGS. 5-6 schematic cross-sectional side view illustrations are provided of heterogenous memory systems including embedded buffer bridge dies in accordance with embodiments. In the embodiment illustrated in FIG. 5, a second column of memory dies 119 can be provided adjacent to the first column of memory die stacks 120A, with the memory dies 119 being of different type than memory dies 118 forming the memory die stacks 120A. For example, the memory die stacks 120A may be designed for HBM, while the memory dies 119 may be designed for DDR memory. In the embodiment illustrated in FIG. 6, the memory die stacks 120B may include less memory dies 118 than the memory die stacks 120A, or lower quality memory dies.

FIG. 7 is a schematic cross-sectional side view illustration of a memory system including an embedded buffer bridge die in accordance with an embodiment. As shown, a single embedded buffer bridge die 142 can span underneath and be electrically connected with a plurality of columns of memory die stacks 120A, 120B. The single embedded buffer bridge die 142 can include separate circuitry for buffering the separate memory die stacks 120A, 120B (e.g., serialization/deserialization (SerDes), buffering, error correction, and test), and may also include partial shared circuitry for the separate memory die stacks 120A, 120B. Additionally, the buffer bridge die can include channel routing for die-to-die connection between the memory die stacks 120A, 120B and the processor. In some embodiments, the buffer bridge die can include repeaters and/or redrivers/retimers for longer channel reach.

In utilizing the various aspects of the embodiments, it would become apparent to one skilled in the art that combinations or variations of the above embodiments are possible for forming a memory system with embedded buffer bridge die. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A memory system comprising:
a routing substrate;
a processor on a first side of the routing substrate;
a memory die stack on the first side of the routing substrate; and
a first buffer bridge die embedded in the routing substrate, and electrically connecting the memory die stack with the processor.

2. The memory system of claim 1, wherein the first buffer bridge die includes serialization/deserialization (SerDes) circuitry, buffering circuitry, error correction circuitry, and test circuitry.

3. The memory system of claim 1, wherein the memory die stack includes 8 or more memory dies.

4. The memory system of claim 1, wherein the memory die stack does not include a logic die.

5. The memory system of claim 1, wherein the routing substrate does not include a silicon base substrate.

6. The memory system of claim 1, wherein the routing substrate is mounted onto a system substrate.

7. The memory system of claim 1, wherein the memory die stack is one of a first plurality of memory die stacks in a first column.

8. The memory system of claim 7, wherein each memory die stack of the first plurality of memory die stacks is connected to the processor with a corresponding buffer bridge die.

9. The memory system of claim 7, wherein each memory die stack of the plurality of memory die stacks is connected to the processor with the first buffer bridge die.

10. The memory system of claim 7, further comprising a second plurality of memory die stacks arranged in a second column adjacent to the first column.

11. The memory system of claim 10, further comprising a second buffer bridge die embedded in the routing substrate and electrically connected to a second memory die stack of the second plurality of memory die stacks.

12. The memory system of claim 11, further comprising a bridge routing chiplet embedded in the routing substrate, the bridge routing chiplet connecting channel routing from the second buffer bridge die to the first buffer bridge die.

13. The memory system of claim 12, wherein the bridge routing chiplet is passive and does not include active devices.

14. The memory system of claim 12, wherein the second buffer bridge die includes serialization/deserialization (SerDes) circuitry, buffering circuitry, error correction circuitry, and test circuitry.

15. The memory system of claim 14, wherein the first buffer bridge die includes repeaters coupled with the channel routing from the second buffer bridge die.
